(19) United States
(12) Patent Application Publication
(10) Pub. No.: US 2023/0272973 A1
(43) Pub. Date: Aug. 31, 2023

(54) SUBSTRATE PROCESSING LIQUID, SUBSTRATE PROCESSING METHOD, AND SUBSTRATE PROCESSING APPARATUS

(71) Applicant: SCREEN Holdings Co., Ltd., Kyoto (JP)

(72) Inventors: Tomoya TANAKA, Kyoto (JP); Masayuki OTSUJI, Kyoto (JP); Takayoshi TANAKA, Kyoto (JP)

(21) Appl. No.: 18/165,193

(22) Filed: Feb. 6, 2023

(30) Foreign Application Priority Data
Feb. 25, 2022 (JP) 2022-027520

(51) Int. Cl. F26B 5/06; H01L 21/67; H01L 21/687; H01L 21/02

(52) U.S. Cl. CPC F26B 5/06; H01L 21/67051; H01L 21/68764; H01L 21/02057; B08B 3/08

(57) ABSTRACT

In the present invention, a substrate processing liquid includes an auxiliary agent which is added to a solution in which a sublimable substance is dissolved in a solvent, to thereby disperse particles of the sublimable substance, the amount of which exceeds the solubility, in the solution. In the substrate processing liquid, the particles of the sublimable substance, the amount of which exceeds the solubility, are uniformly dispersed and dissolved in the solvent. Therefore, the amount of sublimable substance to be supplied onto a pattern formation surface of a substrate is larger than that in the conventional technique and a large amount of sublimable substance (solid phase) exists inside a pattern. As a result, it is possible to effectively suppress the solvent from remaining between the patterns and perform sublimation drying in a state where the patterns are firmly held by the sublimable substance (solid phase).

### CROSS REFERENCE TO RELATED APPLICATION

The disclosure of Japanese Patent Application No. 2022-027520 filed on Feb. 25, 2022 including specification, drawings and claims is incorporated herein by reference in its entirety.

### BACKGROUND OF THE INVENTION

### 1. Field of the Invention

The present invention relates to a substrate processing liquid used for removing a liquid adhered to a substrate by using a sublimation phenomenon of a sublimable substance and relates to a substrate processing method and a substrate processing apparatus for removing the above-described liquid from the substrate by using the substrate processing liquid. Substrates include semiconductor wafers, liquid crystal display substrates, substrates for FPD (Flat Panel Display) such as organic EL (electroluminescence) display device, optical disk substrates, magnetic disk substrates, magneto-optical disk substrates, photomask substrates, ceramic substrates, solar cell substrates and the like.

### 2. Description of the Related Art

A manufacturing process of an electronic component such as a semiconductor device or a liquid crystal display device includes a step of forming a pattern by repeating a process of forming a film or etching on a front surface of a substrate. Further, after this pattern is formed, a cleaning process by a chemical, a rinsing process by a rinse liquid, a drying process and the like are performed in this order. With the miniaturization of patterns, the importance of the drying process has particularly increased. That is, a technique for suppressing or preventing the occurrence of pattern collapse has become important in the drying process. Accordingly, a substrate processing method has been proposed which dries a substrate by sublimation using a processing liquid in which a sublimable substance such as camphor or cyclohexanone oxime is dissolved in IPA (isopropyl alcohol), for example, as described in JP 2021-9988.

### SUMMARY OF THE INVENTION

In the above-described conventional technique, in order to remove DIW (deionized water) adhered to the front surface of the substrate after performing the rinsing process, the following process steps are performed. By supplying IPA onto the front surface of the substrate, the DIW is replaced by the IPA. Then, after the front surface of the substrate is spin coated with the substrate processing liquid, a solvent (IPA) of the substrate processing liquid is evaporated. A solidified film of a sublimable substance is thereby formed on the front surface of the substrate. At the end, the solidified film is sublimated and removed from the front surface of the substrate.

Thus, since the conventional substrate processing liquid uses the solution in which the sublimable substance is dissolved in the solvent, the concentration of the sublimable substance in the solution is low, and sometimes the sublimable substance does not sufficiently fit in a gap between the patterns. In this case, there arises a problem that the solidified film is not formed in the gap between the patterns and the patterns cannot be held. Further, there are some cases where a solidified film is formed on a top layer of the front surface of the substrate and the solvent remains in the solidified film. Due to these factors, there are some cases where the pattern collapse cannot be suppressed.

The present invention is intended to solve the above problem, and it is an object of the present invention to provide a substrate processing liquid, a substrate processing method, and a substrate processing apparatus which make it possible to satisfactorily remove a liquid adhered to a front surface of a substrate with excellent drying performance.

A first aspect of the invention is a substrate processing liquid used for removing a liquid on a substrate having a pattern formation surface. The substrate processing liquid comprises: a sublimable substance; a solvent that dissolves the sublimable substance; and an auxiliary agent that is added to a solution in which the sublimation substance is dissolved in the solvent to disperse particles of the sublimation substance exceeding the solubility in the solution.

A second aspect of the invention is a substrate processing method.

The substrate processing method comprises: (a) preparing the substrate processing liquid; (b) supplying the substrate processing liquid prepared in the operation (a) onto a front surface of a substrate on which a pattern is formed, to thereby form a liquid film of the substrate processing liquid on the front surface of the substrate; (c) solidifying the liquid film of the substrate processing liquid, to thereby form a solidified film of the sublimable substance; and (d) sublimating the solidified film, to thereby remove the solidified film from the front surface of the substrate.

A third aspect of the invention is a substrate processing apparatus. The substrate processing apparatus comprises: a storage part configured to store therein the substrate processing liquid, and a processing liquid supply part configured to supply the substrate processing liquid stored in the storage part onto a front surface of a substrate on which a pattern is formed.

In the present invention having such a configuration, in the substrate processing liquid, the particles of the sublimable substance, the amount of which exceeds the solubility, are uniformly dispersed and dissolved in the solvent. Therefore, the amount of sublimable substance supplied onto the pattern formation surface of the substrate is larger than that in the conventional technique. Moreover, since the particles of the sublimable substance are in a metastable state, when the substrate processing liquid is supplied onto the pattern formation surface of the substrate and enters between the patterns, to thereby reduce flow diffusion thereof, the particles of the sublimable substance are recrystallized between the patterns. Therefore, a large amount of sublimable substance (solid phase) exists inside the pattern. It is thereby possible to effectively suppress the solvent from remaining between the patterns and perform sublimation drying in a state where the patterns are firmly held by the sublimable substance (solid phase).

As described above, it is possible to perform sublimation drying in a state where a solvent is suppressed from remaining between patterns and satisfactorily remove a liquid adhered to a front surface of a substrate with excellent drying performance.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF THE DRAWINGS

FIG. 1 is a view showing an increase in the concentration of a sublimable substance in a substrate processing liquid by adding an auxiliary agent;

FIG. 2 is a plan view showing a schematic configuration of a substrate processing system equipped with a first embodiment of a substrate processing apparatus in accordance with the present invention;

FIG. 3 is a side elevational view showing the substrate processing system shown in FIG. 2;

FIG. 4 is a partial cross section showing a configuration of the first embodiment of the substrate processing apparatus in accordance with the present invention;

FIG. 5 is a block diagram showing an electrical configuration of a controller which controls the substrate processing apparatus;

FIG. 6 is a view showing a configuration of a processing liquid supply part;

FIG. 7 is a view showing details of substrate processing performed by the substrate processing apparatus shown in FIG. 2;

FIG. 8 is a flowchart showing an operation of a purification apparatus shown in FIG. 6;

FIG. 9A is a view schematically showing a first exemplary operation of the purification apparatus shown in FIG. 6;

FIG. 9B is a view schematically showing a second exemplary operation of the purification apparatus shown in FIG. 6;

FIG. 9C is a view schematically showing a third exemplary operation of the purification apparatus shown in FIG. 6;

FIG. 9D is a view schematically showing a fourth exemplary operation of the purification apparatus shown in FIG. 6;

FIG. 9E is a view schematically showing a fifth exemplary operation of the purification apparatus shown in FIG. 6; and

FIG. 10 is a view showing a configuration of a substrate processing system equipped with a second embodiment of the substrate processing apparatus in accordance with the present invention.

### DETAILED DESCRIPTION OF THE PREFERRED EMBODIMENTS

### <Substrate Processing Liquid>

Hereinafter, a substrate processing liquid in accordance with embodiments of the present invention will be described.

In this specification, the “substrate” means various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates. In this specification, the “pattern-formed surface” means a surface on which an uneven pattern is formed in an arbitrary region of a substrate, regardless of whether it is planar, curved, or uneven. Further, in this specification, the “sublimability” means to have a property of phase transition of a single substance, a compound or a mixture from a solid state to a gaseous state or from a gaseous state to a solid state without passing through a liquid state and the “sublimable substance” means a substance having such sublimability.

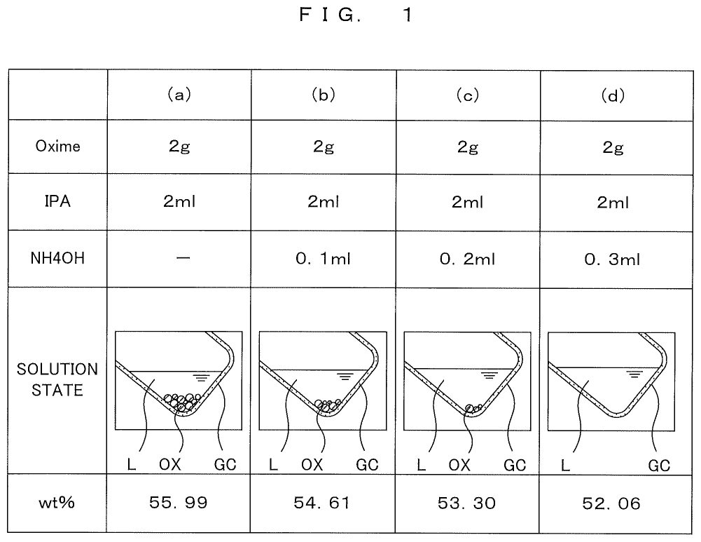

The substrate processing liquid in accordance with the present invention includes a sublimable substance such as camphor, cyclohexanone oxime, or the like used for sublimation drying, a solvent such as IPA or the like in which the sublimable substance is dissolved, and an auxiliary agent added to a solution in which the sublimable substance is dissolved in the solvent, to thereby disperse particles of the sublimable substance, the amount of which exceeds the solubility, in the solution. Thus, in the present embodiment, by adding the auxiliary agent to the substrate processing liquid (hereinafter, referred to as the “conventional substrate processing liquid”) used in the conventional technique, the concentration of the particles of the sublimable substance which are uniformly dispersed in the substrate processing liquid is increased to be higher than the saturation concentration of the sublimable substance with respect to the conventional substrate processing liquid and the particles of the sublimable substance are uniformly dispersed in a so-called metastable state. In other words, the substrate processing liquid of the present embodiment is a supersaturated solution of the sublimable substance. In a case, for example, where cyclohexanone oxime is used as the sublimable substance, IPA can be used as the solvent and aqueous ammonia can be used as the auxiliary agent. Hereinafter, the substrate processing liquid obtained by purifying a mixture of cyclohexanone oxime (sublimable substance), IPA (solvent), and aqueous ammonia (auxiliary agent) will be described with reference to FIG. 1.

Herein, prior to description of the substrate processing liquid, the solubility of cyclohexanone oxime in IPA will be described. JP 2021-9988A discloses a substrate processing liquid in which cyclohexanone oxime is dissolved in IPA. More specifically, exemplarily shown is sublimation drying using the substrate processing liquids in which the content amount of cyclohexanone oxime ranges from 0.1 vol % (0.13 wt %) to 10 vol % (12.97 wt %). These conventional substrate processing liquids each have favorable solubility. As described in JP 2021-9988A, this “solubility” means that, for example, 10 g or more of cyclohexanone oxime is dissolved in 100 g of solvent at 23° C. The “ordinary temperature” means a temperature range of 5° C. to 35° C.

No specific description, however, is made on the solubility of cyclohexanone oxime, i.e., the limit amount of cyclohexanone oxime which can be dissolved in a certain amount of IPA. Then, the present inventor performed a demonstration experiment in which 4 g of cyclohexanone oxime is put in transparent glass containers storing therein different amounts of IPA, respectively, and stirred to be sufficiently mixed, and the transparent glass containers are left at rest and precipitation is checked. As a result, it was proved that 8.3 ml of IPA is needed to dissolve 4 g of cyclohexanone oxime in a saturated state. Specifically, it was found, from the above-described demonstration experiment, that the saturation concentration of cyclohexanone oxime in the substrate processing liquid is about 38 wt %.

In a solution in which cyclohexanone oxime is dissolved at the limit concentration, i.e., in a saturated solution, solution equilibrium is established. In other words, though the dissolution reaction in which cyclohexanone oxime (solid phase) is dissolved and a reaction of recrystallization of cyclohexanone oxime dispersed in the solution are apparently stopped, the dissolution and the recrystallization are actually performed at the same speed. Then, when an auxiliary agent (crystallization inhibitor) for inhibiting crystallization is added to the solution, the speed of recrystallization becomes lower. Therefore, the present inventor reasoned that the solution becomes a solution in which the solution equilibrium is lost and the metastable state is established, where the concentration of cyclohexanone oxime particles becomes higher than the above-described saturation concentration, i.e., a supersaturated solution of cyclohexanone oxime.

Further, by adjusting pH of the above-described solution, the cyclohexanone oxime particles have a negative zeta potential thereby increasing the repulsion between the cyclohexanone oxime particles. As a result, the crystallization is inhibited. Based on such a consideration, the present inventor selects aqueous ammonia as one example of a pH adjuster for making the zeta potential of the cyclohexanone oxime particles negative, i.e., the “auxiliary agent” of the present invention. Then, as shown in FIG. 1, it is verified that by using the aqueous ammonia as the auxiliary agent, the concentration of the cyclohexanone oxime particles in the substrate processing liquid becomes higher than the saturation concentration and the cyclohexanone oxime particles become a metastable state. Further, the auxiliary agent is not limited to the aqueous ammonia, but the pH adjuster for making the zeta potential of the cyclohexanone oxime particles negative can be generally used.

FIG. 1 is a view showing an increase in the concentration of the sublimable substance in the substrate processing liquid by adding the auxiliary agent. In FIG. 1, the row of “Oxime” shows the weight of cyclohexanone oxime which is one example of the “sublimable substance” in the present invention, the row of “IPA” shows the quantity of IPA which is one example of the “solvent” in the present invention, and the row of “NH₄OH” shows the addition amount of aqueous ammonia which is one example of the “auxiliary agent” in the present invention. The cyclohexanone oxime and the IPA (and the aqueous ammonia) are stirred and mixed in a transparent glass container GC, to thereby generate a substrate processing liquid L. After that, the transparent glass container GC is left at rest, and a solution state of the cyclohexanone oxime is schematically shown. Further, in FIG. 1, the row of “wt %” shows the weight percentage of cyclohexanone oxime in the substrate processing liquid. Furthermore, a hatched solid matter OX in the “solution state” shows cyclohexanone oxime (solid phase).

Herein, a solution is created by dissolving 2 g of cyclohexanone oxime solid matter OX in 2 ml of IPA. In this solution, as shown in the column (a) of FIG. 1, the concentration of the cyclohexanone oxime is 55.9 wt %, which exceeds the saturation concentration (38 wt %). A large amount of cyclohexanone oxime solid matter OX exists in the transparent glass container GC. When aqueous ammonia is added to a solution having the same composition as this solution, as shown in the columns (b) to (d) of FIG. 1, as the addition amount of aqueous ammonia increases, the remaining amount of cyclohexanone oxime solid matter OX decreases, and when the addition amount is 0.3 ml, 2 g of cyclohexanone oxime solid matter OX is completely dissolved. At that time, generated is the substrate processing liquid L in which the concentration of cyclohexanone oxime is 52.06 wt %. This means that the cyclohexanone oxime particles are uniformly dispersed in the substrate processing liquid L with the concentration which is about four to four hundred times as high as the concentration of the substrate processing liquid (containing 0.13 to 12.97 wt % of cyclohexanone oxime) disclosed in JP 2021-9988A. Thus, the substrate processing liquid L containing high-concentration cyclohexanone oxime particles is obtained. Therefore, as described later, after the pattern formation surface of the substrate is spin coated with the substrate processing liquid L, the solvent (IPA) of the substrate processing liquid is evaporated. Moreover, since the substrate processing liquid of the present invention is a supersaturated solution of cyclohexanone oxime and is in a so-called metastable state, the recrystallization of the cyclohexanone oxime particles is started immediately after the spin coating. With the recrystallization and the solvent evaporation, a larger amount of cyclohexanone oxime (solid phase) than that in the case of using the conventional substrate processing liquid enters a gap between the patterns. As a result, it is possible to satisfactorily remove a liquid adhered to the front surface of the substrate with excellent drying performance.

Further, though cyclohexanone oxime is used as the sublimable substance in the present embodiment, the same applies to a case where any other sublimable substance for sublimation drying, such as camphor or the like, is used. Furthermore, though IPA is used as the solvent, any substance having a function of dissolving the above-described sublimable substance may be used, and as described in, for example, JP 2021-9988A, at least one type selected from a group consisting of alcohols, ketones, ethers, cycloalkanes, and water may be used. Further, though aqueous ammonia is used as the auxiliary agent, a crystallization inhibitor having a function of inhibiting the recrystallization of the particles of the sublimable substance dissolved in the solvent by adjusting the pH of the solution in which the sublimable substance is dissolved in the solvent, other than this, may be used.

### <Single Wafer Type Substrate Processing System>

Next, a substrate processing system equipped with a substrate processing apparatus for processing a substrate having a pattern formation surface by using the above-described substrate processing liquid (=the sublimable substance+the solvent+the auxiliary agent).

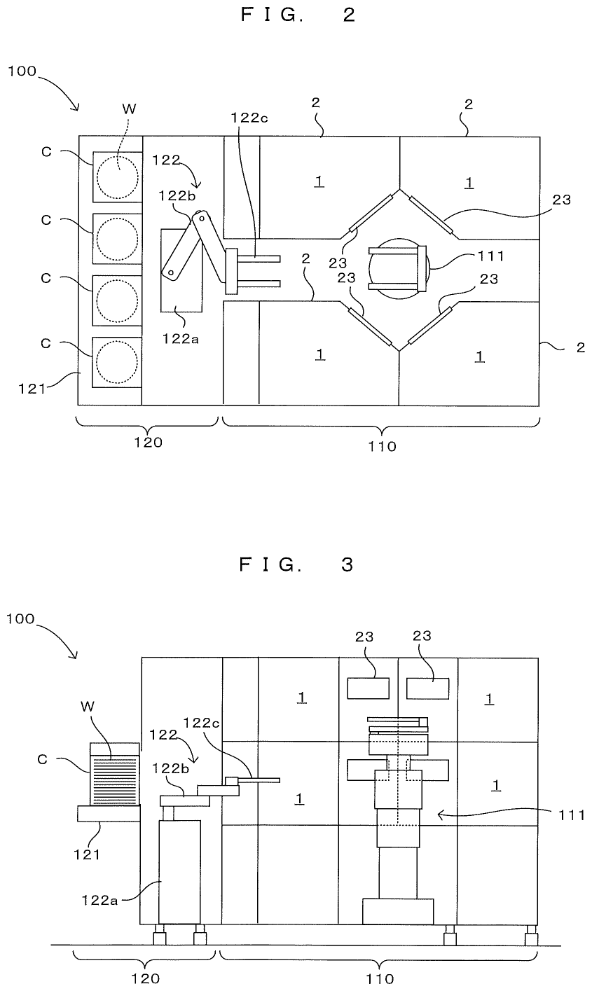

FIG. 2 is a plan view showing a schematic configuration of a substrate processing system equipped with a first embodiment of a substrate processing apparatus in accordance with the present invention. Further, FIG. 3 is a side elevational view showing the substrate processing system shown in FIG. 2. These figures are diagrams not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. A first embodiment of a substrate processing method according to the invention is carried out in the substrate processing system 100. In this specification, a pattern formation surface (one principal surface) formed with the pattern is referred to as a “front surface Wf” and the other principal surface not formed with the pattern on an opposite side is referred to as a “back surface Wb”. Though description will be made hereinafter mainly with the substrate processing system used for processing semiconductor wafers taken as an example with reference to drawings, the same can apply to processing of various substrates exemplarily shown above.

As shown in FIG. 2, the substrate processing system 100 includes a substrate processing station 110 for processing the substrate W and an indexer station 120 coupled to this substrate processing station 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate W from the container C by accessing the container C held by the container holder 121 and housing a processed substrate W in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate W can be placed and held on the upper surface thereof. Such an indexer robot including the articulated arm and the hand for holding the substrate is not described in detail since being known.

The substrate processing station 110 includes a substrate conveyor robot 111 arranged substantially in a center in a plan view and a plurality of processing apparatuses 1 arranged to surround this substrate conveyor robot 11. Specifically, the plurality of (eight in this example) processing apparatuses 1 are arranged to face a space where the substrate conveyor robot 111 is arranged. The substrate conveyor robot 111 randomly accesses these processing apparatuses 1 and transfers the substrates W. On the other hand, each processing apparatus 1 performs a predetermined processing to the substrate W. In this embodiment, these processing apparatuses 1 have the same function. Thus, a plurality of the substrates W can be processed in parallel.

### <Configuration of Processing Apparatus 1>

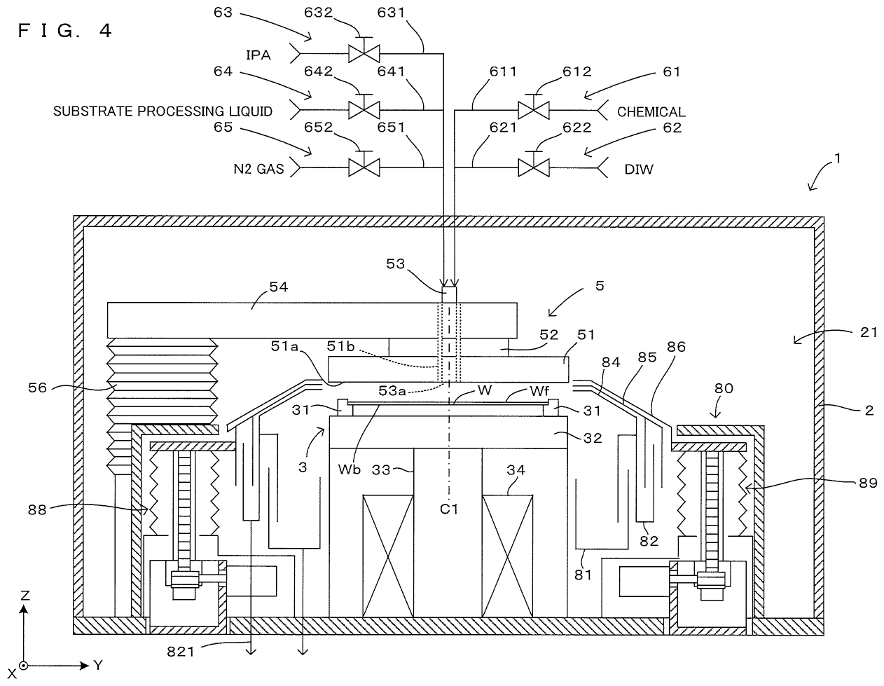

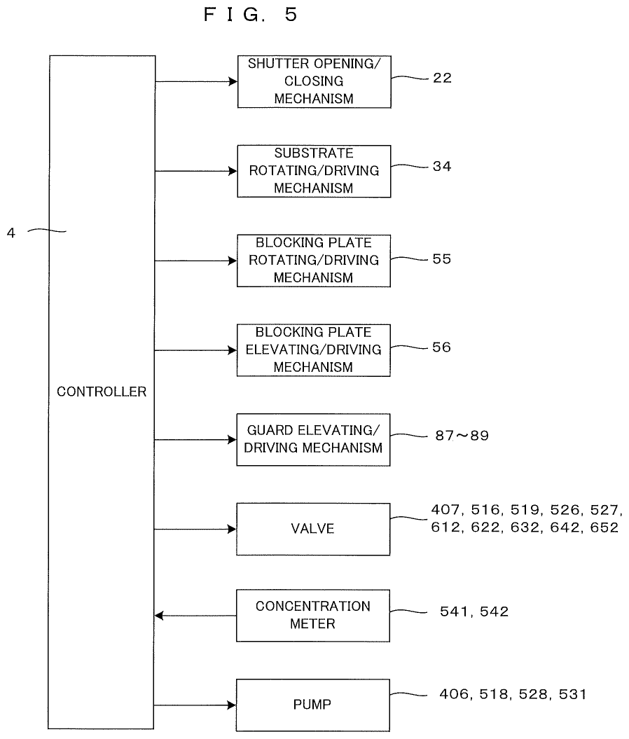

FIG. 4 is a partial sectional view showing the configuration of the processing unit. FIG. 5 is a block diagram showing an electrical configuration of a controller for controlling the processing unit. Note that although a controller 4 is provided for each processing apparatus 1 in this embodiment, the plurality of processing apparatuses 1 may be controlled by one controller. Further, the processing apparatuses 1 may be controlled by a control unit (not shown) for controlling the entire substrate processing system 100.

The processing apparatus 1 includes a chamber 2 having an internal space 21 and a spin chuck 3 housed in the internal space 21 of the chamber 2 to hold the substrate W. As shown in FIGS. 1 and 2, a shutter 23 is provided on a side surface of the chamber 2. A shutter opening/closing mechanism 22 (FIG. 4) is connected to the shutter 23, and the shutter 23 is opened/closed in response to an open/close command from the controller 4. More specifically, in the processing apparatus 1, the shutter opening/closing mechanism 22 opens the shutter 23 when an unprocessed substrate W is carried into the chamber 2, and the unprocessed substrate W is carried to the spin chuck 3 in a face-up state by the hand of the substrate conveyor robot 111. That is, the substrate W is placed on the spin chuck 3 with the front surface Wf faced up. If the hand of the substrate conveyor robot 111 is retracted from the chamber 2 after the substrate is carried in, the shutter opening/closing mechanism 22 closes the shutter 23. Then, a desired substrate processing is performed in a normal temperature environment by supplying a chemical, DIW (deionized water), an IPA, a processing liquid for sublimation drying and a nitrogen gas to the front surface Wf of the substrate W as described later in the internal space 21 of the chamber 2. Further, after the substrate processing is finished, the shutter opening/closing mechanism 22 opens the shutter 23 again and the hand of the substrate conveyor robot 111 carries out the processed substrate W from the spin chuck 3. As just described, in this embodiment, the internal space 21 of the chamber 2 functions as a processing space in which the substrate processing is performed while the normal temperature environment is maintained. Note that the “normal temperature” means a temperature range of 5° C. to 35° C. in this specification.

The spin chuck 3 includes a plurality of chuck pins 31 for holding the substrate W, a spin base 32 formed into a disk shape along a horizontal direction to support the plurality of chuck pins 31, a center shaft 33 provided rotatably about an axis of rotation C1 parallel to a surface normal extending from a center of the front surface of the substrate W while being coupled to the spin base 32, and a substrate rotating/driving mechanism 34 for rotating the center shaft 33 about the axis of rotation C1 by a motor. The plurality of chuck pins 31 are provided on a peripheral edge part of the upper surface of the spin base 32. In this embodiment, the chuck pins 31 are arranged at equal intervals in a circumferential direction. If the motor of the substrate rotating/driving mechanism 34 operates in response to a rotation command from the controller 4 with the substrate W placed on the spin chuck 3 held by the chuck pins 31, the substrate W rotates about the axis of rotation C1. Further, the chemical, the IPA, the DIW, the processing liquid and the nitrogen gas are successively supplied to the front surface Wf of the substrate W from a nozzle provided in an atmosphere blocking mechanism 5 in response to a supply command from the controller 4.

The atmosphere blocking mechanism 5 includes a blocking plate 51, an upper spin shaft 52 provided to be integrally rotatable with the blocking plate 51 and a nozzle 53 penetrating in a vertical direction through a central part of the blocking plate 51. The blocking plate 51 is finished into a disk shape having a diameter substantially equal to or larger than that of the substrate W. The blocking plate 51 is arranged to face the upper surface of the substrate W held by the spin chuck 3 while being spaced apart. Thus, the lower surface of the blocking plate 51 functions as a circular substrate facing surface 51a facing the entire front surface Wf of the substrate W. Further, a hollow cylindrical through hole 51b penetrating in the vertical direction through the blocking plate 51 is formed in a central part of the substrate facing surface 51a.

The upper spin shaft 52 is provided rotatably about an axis of rotation (axis coinciding with the axis of rotation C1 of the substrate W) vertically extending through a center of the blocking plate 51. The upper spin shaft 52 has a hollow cylindrical shape. The inner peripheral surface of the upper spin shaft 52 is formed into a cylindrical surface centered on the above axis of rotation. An internal space of the upper spin shaft 52 communicates with the through hole 51b of the blocking plate 51. The upper spin shaft 52 is supported relatively rotatably on a support arm 54 horizontally extending above the blocking plate 51.

The nozzle 53 is arranged above the spin chuck 3. The nozzle 53 is supported by the support arm 54 in a state unrotatable with respect to the support arm 54. Further, the nozzle 53 is movable upward and downward integrally with the blocking plate 51, the upper spin shaft 52 and the support arm 54. A discharge port 53a is provided in a lower end part of the nozzle 53 and facing a central part of the front surface Wf of the substrate W held by the spin chuck 3.

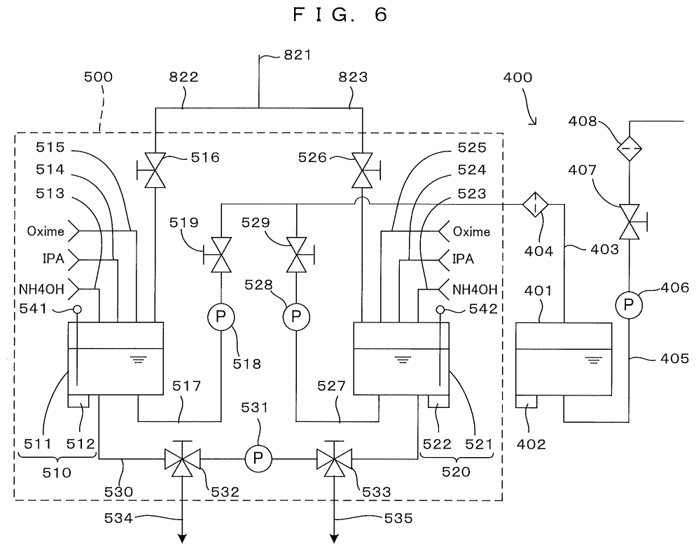

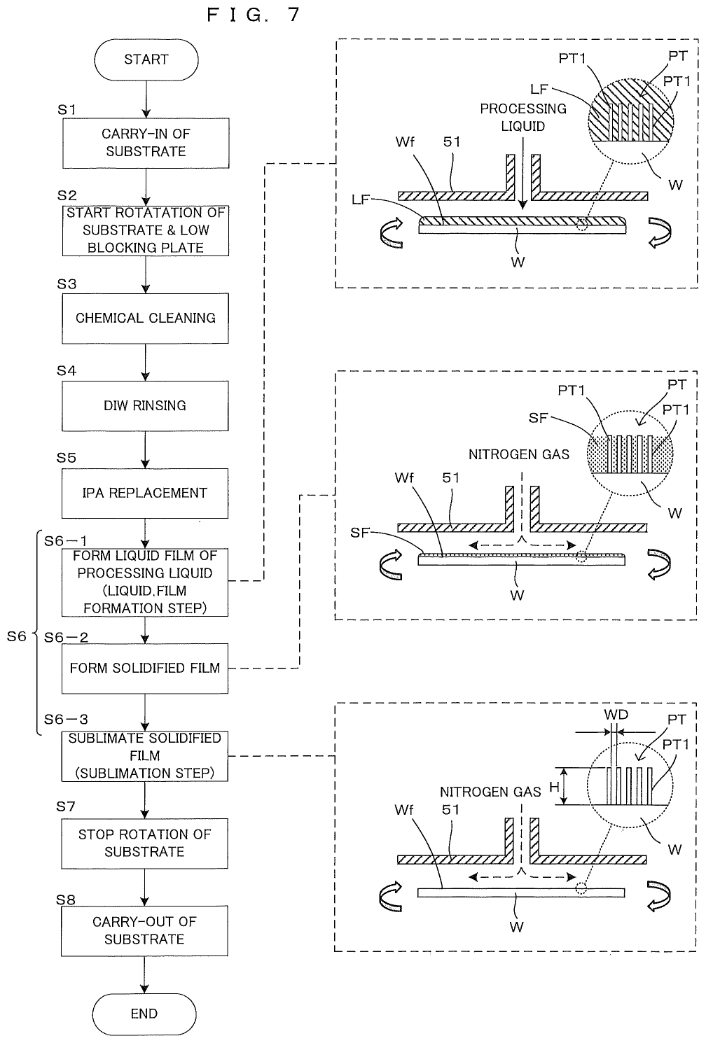

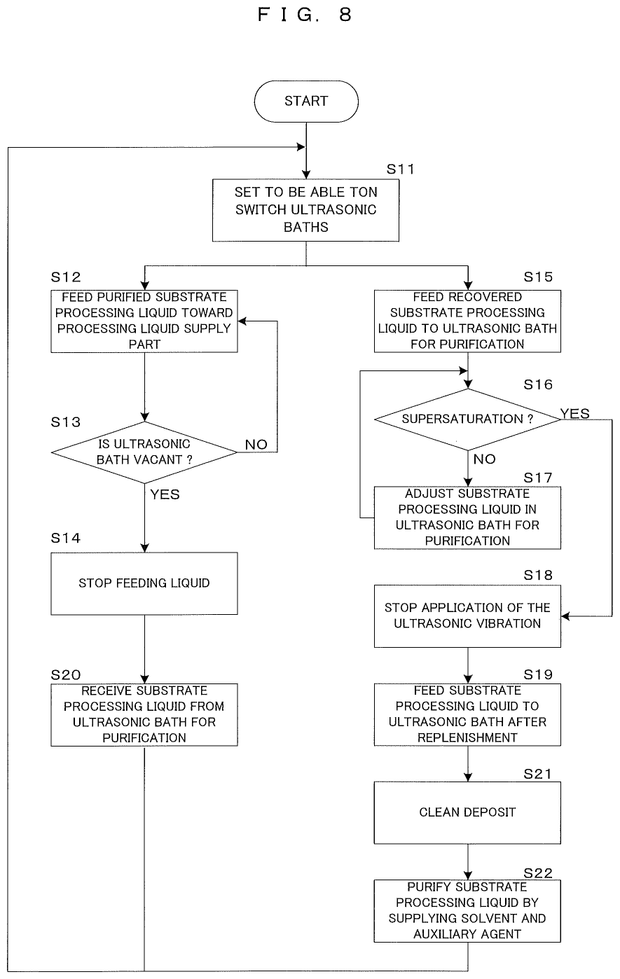

A blocking plate rotating/driving mechanism 55 (FIG. 5) including an electric motor and the like is coupled to the blocking plate 51. The blocking plate rotating/driving mechanism 55 rotates the blocking plate 51 and the upper spin shaft 52 about the axis of rotation C1 with respect to the support arm 54 in response to a rotation command from the controller 4. Further, a blocking plate elevating/driving mechanism 56 is coupled to the support arm 54. The blocking plate elevating/driving mechanism 56 integrally moves the blocking plate 51, the upper spin shaft 52 and the nozzle 53 upward and downward in a vertical direction Z in response to an elevation command from the controller 4. More specifically, the blocking plate elevating/driving mechanism 56 moves the blocking plate 51, the upper spin shaft 52 and the nozzle 53 upward and downward between a blocking position (position shown in FIG. 4 and right-upper stages of FIGS. 6 and 7) where the substrate facing surface 51a is proximate to the front surface Wf of the substrate W held by the spin chuck 3 to substantially block a space above the front surface Wf from a surrounding atmosphere and a retracted position (position shown in right-middle and right-lower stages of FIG. 7, position shown in FIG. 8) retracted largely upward from the blocking position.

A chemical supply unit 61, a rinse liquid supply unit 62, an organic solvent supply unit 63, a processing liquid supply unit 64 and a gas supply unit 65 are connected to an upper end part of the nozzle 53.

The chemical supply unit 61 includes a chemical piping 611 connected to the nozzle 53 and a valve 612 disposed in the chemical piping 611. The chemical piping 611 is connected to a chemical supply source. In this embodiment, the chemical only has to have a function of cleaning the front surface Wf of the substrate W. For example, a chemical containing at least one of hydrofluoric acid (HF), hydrochloric acid, sulfuric acid, phosphoric acid and nitric acid can be, for example, used as an acidic chemical. Further, a chemical containing at least one of ammonia and a hydroxyl group can be, for example, used as an alkaline chemical. Note that, in this embodiment, hydrofluoric acid is used as the chemical. Thus, if the valve 612 is opened in response to an open/close command from the controller 4, a hydrofluoric acid chemical is supplied to the nozzle 53 and discharged toward a front surface central part of the substrate W from the discharge port 53a.

The rinse liquid supply unit 62 includes a rinse liquid piping 621 connected to the nozzle 53 and a valve 622 disposed in the rinse liquid piping 621. The rinse liquid piping 621 is connected to a rinse liquid supply source. In this embodiment, DIW is used as the rinse liquid. If the valve 622 is opened in response to an open/close command from the controller 4, the DIW is supplied to the nozzle 53 and discharged toward the front surface central part of the substrate W from the discharge port 53a. Note that, besides the DIW, any one of carbonated water, electrolytic ionized water, hydrogen water, ozone water and hydrochloric acid water having a diluted concentration (e.g. about 10 ppm to 100 ppm) may be used as the rinse liquid.

The organic solvent supply unit 63 is a unit for supplying an organic solvent having a larger specific weight than air, having a lower surface tension than water and serving as a low surface tension liquid. The organic solvent supply unit 63 includes an organic solvent piping 631 connected to the nozzle 53 and a valve 632 disposed in the organic solvent piping 631. The organic solvent piping 631 is connected to an organic solvent supply source. In this embodiment, IPA is used as the organic solvent. If the valve 632 is opened in response to an open/close command from the controller 4, the IPA is supplied to the nozzle 53 and discharged toward the front surface central part of the substrate W from the discharge port 53a. Note that, besides the IPA, methanol, ethanol, acetone, EG (ethylene glycol) and HFE (hydrofluoroether) can be, for example, used as the organic solvent. Further, the organic solvent may be not only composed of a single component, but also a liquid mixed with other component(s). For example, the organic solvent may be a mixed liquid of IPA and acetone or a mixed liquid of IPA and methanol.

The processing liquid supply unit 64 is a unit for supplying a processing liquid for sublimation drying functioning as a drying auxiliary liquid in drying the substrate W held by the spin chuck 3 to the front surface Wf of the substrate W. The processing liquid supply unit 64 includes a processing liquid piping 641 connected to the nozzle 53 and a valve 642 disposed in the processing liquid piping 641. The processing liquid piping 641 is connected to a processing liquid supply part functioning as a processing liquid supply source for sublimation drying.

FIG. 6 is a view showing a configuration of a processing liquid supply part. A processing liquid supply part 400 includes a purification apparatus 500 for purifying the above-described substrate processing liquid and a storage tank 401 for storing therein the substrate processing liquid purified by the purification apparatus 500. Further, to the storage tank 401, attached is an ultrasonic wave applying part 402 having a vibrator for generating an ultrasonic wave, and when the ultrasonic wave applying part 402 starts operating in response to a vibration command from the controller 4, ultrasonic vibration is applied to the substrate processing liquid stored in the storage tank 401.

The purification apparatus 500 is an apparatus for removing liquid-borne particles from a used substrate processing liquid or an undiluted solution of a substrate processing liquid provided by a chemical manufacturer, to thereby purify a high purity supersaturated solution of cyclohexanone oxime as the substrate processing liquid. Herein, the “used substrate processing liquid” refers to a substrate processing liquid recovered from a substrate W by a cup in spin coating as described later. The “undiluted solution of a substrate processing liquid provided by a chemical manufacturer” refers to a cyclohexanone oxime solution (for example, 3 wt % of cyclohexanone oxime solution) obtained in the chemical manufacturer, by dissolving cyclohexanone oxime in IPA.

In order to feed the substrate processing liquid (=the sublimable substance+the solvent+the auxiliary agent) purified by the purification apparatus 500 to the storage tank 401, the purification apparatus 500 and the storage tank 401 are connected to each other with a piping 403 in which a filter 404 is disposed. Therefore, while the substrate processing apparatus 1 operates, the purification apparatus 500 also operates concurrently and intermittently purifies the substrate processing liquid for sublimation drying and feeds the substrate processing liquid to the storage tank 401 through the piping 403. Then, the storage tank 401 stores therein the purified substrate processing liquid. Further, a configuration, a purification operation, and the like of the purification apparatus 500 will be described in detail after the substrate processing method is described.

A bottom of the storage tank 401 is connected to the processing liquid piping 641 with a piping 405. In this piping 405, a pump 406, a valve 407, and a filter 408 are disposed. When the pump 406 starts operating and the valve 407 is opened on the basis of a control command from the controller 4, the above-described substrate processing liquid is fed from the processing liquid supply part 400 to the nozzle 53. As a result, while the valve 642 is opened, the substrate processing liquid (the supersaturated solution of cyclohexanone oxime) is supplied from the nozzle 53 onto the front surface Wf of the substrate W.

Further, in the present embodiment, though not shown in FIG. 6, an ultrasonic wave applying part is provided along a supply path (the piping 405, the processing liquid piping 641, and the nozzle 53) of the substrate processing liquid from the storage tank 401. Application of the ultrasonic vibration to the substrate processing liquid continues until the substrate processing liquid is supplied onto the substrate W, and the metastable state is kept. In other words, it is possible to effectively suppress crystallization of the cyclohexanone oxime particles contained in the substrate processing liquid. As a result, it is possible to reliably supply the substrate processing liquid in the metastable state onto the front surface Wf of the substrate W. Further, the manner of application of the ultrasonic vibration to the substrate processing liquid is arbitrary, and for example, a vibrator may be incorporated in the nozzle 53. Furthermore, the vibrator may be provided adjacent to the nozzle 53.

With reference back to FIG. 4, description will continue. After the substrate processing liquid is fed to the nozzle 53 as described above, the substrate processing liquid is discharged toward the front surface central part of the substrate W from the discharge port 53a of the nozzle 53.

The gas supply unit 65 includes a gas supply piping 651 connected to the nozzle 53 and a valve 652 for opening and closing the gas supply piping 651. The gas supply piping 651 is connected to a gas supply source. In this embodiment, a dehumidified nitrogen gas is used as a gas. If the valve 652 is opened in response to an open/close command from the controller 4, the nitrogen gas is supplied to the nozzle 53 and blown toward the front surface central part of the substrate W from the discharge port 53a. Note that an inert gas such as a dehumidified argon gas may be used as the gas besides the nitrogen gas.

In the processing apparatus 1, an exhaust tub 80 is provided to surround the spin chuck 3. Further, a plurality of cups 81, 82 (first cup 81 and second cup 82) and a plurality of guards 84 to 86 (first to third guards 84 to 86) for receiving the processing liquid scattered around the substrate W are arranged between the spin chuck 3 and the exhaust tub 80. Further, guard elevating/driving mechanisms 87 to 89 (first to third guard elevating/driving mechanisms 87 to 89) are respectively coupled to the guards 84 to 86. The respective guard elevating/driving mechanisms 87 to 89 independently move the guards 84 to 86 upward and downward in response to an elevation command from the controller 4. Further, the first guard elevating/driving mechanism 87 is not shown in FIG. 4. Furthermore, the second guard 85 among three guards faces the peripheral end surface of the substrate W in spin coating of the substrate processing liquid (a liquid film formation step S6-1 described later). Therefore, the substrate processing liquid shaken off from the substrate W is collected by the second guard 85 and recovered by the second cup 82. Then, the recovered substrate processing liquid is fed to the purification apparatus 500 through a recovery piping 821 and subjected to reuse after being purified.

The controller 4 includes an arithmetic unit such as a CPU, a storage unit such as a fixed memory device or a hard disk drive, and an input/output unit. A program to be executed by the arithmetic unit is stored in the storage unit. The controller 4 performs a substrate processing shown in FIG. 7 using the metastable processing liquid that dissolves cyclohexanone oxime to supersaturation.

### <Substrate Processing Method>

Next, the substrate processing method using the substrate processing system 100 shown in FIG. 2 is described with reference to FIG. 7. FIG. 7 is a view showing contents of the substrate processing performed in the substrate processing apparatus of FIG. 1. In FIG. 6 (and FIGS. 7 and 8 to be described later), a flow chart of the substrate processing performed in one processing apparatus 1 is shown on a left side. Further, a liquid film formation step, a solidified film formation step and a sublimation step are schematically shown and a part of the front surface Wf of the substrate W is enlargedly shown in right-upper, right-middle and right-lower stages. However, for the purpose of facilitating understanding, dimensions, numbers and the like of parts are shown in an exaggerated or simplified manner if necessary.

A processing target in the substrate processing system 100 is, for example, a silicon wafer, and an uneven pattern PT is formed on a front surface Wf, which is a pattern formation surface. In this embodiment, projections PT1 have a height in a range of 100 to 600 nm and a width in a range of 5 to 50 nm. A shortest distance between two adjacent projections PT1 (shortest width of a recess) is in a range of 5 to 150 nm. An aspect ratio, i.e. a value obtained by dividing a height by a width (height H/width WD), of the projections PT1 is 5 to 35.

Further, the pattern PT may be such that linear pattern elements formed by fine trenches are repeatedly arranged. Further, the pattern PT may be formed by providing a plurality of fine holes (voids or pores) in a thin film. The pattern PT includes, for example, an insulation film. Further, the pattern PT may include a conductive film. More specifically, the pattern PT may be formed by a laminated film obtained by laminating a plurality of films and further include an insulation film and a conductive film. The pattern PT may be a pattern constituted by a single-layer film. The insulation film may be a silicon oxide film or a silicon nitride film. Further, the conductive film may be an amorphous silicon film having impurities introduced thereto to reduce resistance or may be a metal film (e.g. TiN film). Further, the pattern PT may be formed by a front-end process or may be formed by a back-end process. Furthermore, the pattern PT may be a hydrophobic film or may be a hydrophilic film. Examples of the hydrophilic film include a TEOS film (one type of a silicon oxide film).

Further, each step shown in FIG. 7 is processed in an atmospheric environment unless otherwise specified. Here, the atmospheric environment indicates an environment at 0.7 atmospheres to 1.3 atmospheres with respect to normal atmospheric pressure (1 atmosphere, 1013 hPa). Particularly, if the substrate processing system 100 is arranged in a clean room at a positive pressure, an environment for the front surface Wf of the substrate W is higher than one atmosphere.

Before an unprocessed substrate W is carried into the processing apparatus 1, the controller 4 gives a command to each part of the apparatus and the processing apparatus 1 is set in an initial state. Specifically, the shutter 23 (FIGS. 2, 3) is closed by the shutter opening/closing mechanism 22. The spin chuck 3 is positioned and stopped at a position suitable for the loading of the substrate W by the substrate rotating/driving mechanism 34, and the chuck pins 31 are set in an open state by an unillustrated chuck opening/closing mechanism. The blocking plate 51 is positioned at the retracted position by the blocking plate elevating/driving mechanism 56, and the rotation of the blocking plate 51 by the blocking plate rotating/driving mechanism 55 is stopped. Any of the guards 84 to 86 is moved downward and positioned. Further, any of the valves 612, 622, 632, 642 and 652 is closed.

When the unprocessed substrate W is conveyed by the substrate conveyor robot 111, the shutter 23 is opened. As the shutter 23 is opened, the substrate W is carried into the internal space 21 of the chamber 2 by the substrate conveyor robot 111 and transferred to the spin chuck 3 with a front surface Wf faced up. Then, the chuck pins 31 are set in a closed state and the substrate W is held by the spin chuck 3 (Step S1: carry-in of the substrate).

Following the carry-in of the substrate W, the substrate conveyor robot 111 is retracted to the outside of the chamber 2. Further, after the shutter 23 is closed again, the controller 4 increases a rotation speed (number of rotations) of the spin chuck 3 to a predetermined processing speed (e.g. 800 to 1200 rpm within a range of about 10 to 3000 rpm) by controlling the motor of the substrate rotating/driving mechanism 34 and maintains that processing speed. Further, the controller 4 lowers the blocking plate 51 from the retracted position and arranges the blocking plate 51 at the blocking position by controlling the blocking plate elevating/driving mechanism 56 (Step S2). Further, the controller 4 causes the first guard 84 to face a peripheral end surface of the substrate W by controlling the guard elevating/driving mechanisms 87 to 89 and raising the first to third guards 84 to 86 to upper positions.

When the rotation of the substrate W reaches the processing speed, the controller 4 subsequently opens the valve 612. In this way, the chemical (HF in this embodiment) is discharged from the discharge port 53a of the nozzle 53 and supplied to the front surface Wf of the substrate W. On the front surface Wf of the substrate W, the HF moves to a peripheral edge part of the substrate W by receiving a centrifugal force caused by the rotation of the substrate W. In this way, the entire front surface Wf of the substrate W is cleaned by the HF (Step S3). At this time, the HF having reached the peripheral edge part of the substrate W is discharged laterally of the substrate W from the peripheral edge part of the substrate W, received by an inner wall of the first guard 84 and fed to a waste liquid processing facility outside the apparatus along an unillustrated waste liquid path. This chemical cleaning by the supply of the HF is continued for a cleaning time determined in advance. Upon the elapse of the cleaning time, the controller 4 closes the valve 612 and stops the discharge of the HF from the nozzle 53.

Following the chemical cleaning, the rinsing process by the rinse liquid (DIW) is performed (Step S4). In this DIW rinsing, the controller 4 opens the valve 622 while maintaining the positions of the first to third guards 84 to 86. In this way, the DIW is supplied as the rinse liquid from the discharge port 53a of the nozzle 53 to a central part of the front surface Wf of the substrate W subjected to the chemical cleaning process. Then, the DIW moves to the peripheral edge part of the substrate W by receiving the centrifugal force caused by the rotation of the substrate W. In this way, the HF adhering on the substrate W is washed away by the DIW. At this time, the DIW discharged from the peripheral edge part of the substrate W is discharged laterally of the substrate W from the peripheral edge part of the substrate W and fed to the waste liquid processing facility outside the apparatus similarly to the HF. This DIW rinsing is continued for a rinsing time determined in advance. Upon the elapse of the rinsing time, the controller 4 closes the valve 622 and stops the discharge of the DIW from the nozzle 53.

After the DIW rinsing is completed, a replacement process by an organic solvent (IPA in this embodiment) having a lower surface tension than the DIW is performed (Step S5). In IPA replacement, the controller 4 causes the third guard 86 to face the peripheral end surface of the substrate W by controlling the guard elevating/driving mechanisms 87, 88 and lowering the first and second guards 84, 85 to lower positions. Then, the controller 4 opens the valve 632. In that way, the IPA is discharged as a low surface tension liquid toward the central part of the front surface Wf of the substrate W having the DIW adhered thereto from the discharge port 53a of the nozzle 53. The IPA supplied to the front surface Wf of the substrate W spreads over the entire front surface Wf of the substrate W by receiving the centrifugal force caused by the rotation of the substrate W. In this way, the DIW (rinse liquid) adhering to the front surface Wf is replaced by the IPA in the entire front surface Wf of the substrate W. Note that the IPA moving on the front surface Wf of the substrate W is discharged laterally of the substrate W from the peripheral edge part of the substrate W, received by an inner wall of the third guard 86 and fed to a recovery facility along an unillustrated recovery path. This IPA replacement is continued for a replacement time determined in advance. Upon the elapse of the replacement time, the controller 4 closes the valve 632 and stops the discharge of the IPA from the nozzle 53.

Following the IPA replacement, a sublimation drying step (Step S6) corresponding to a first embodiment of the substrate processing method of the invention is performed. This sublimation drying step includes a liquid film formation step of forming a liquid film of the processing liquid (Step S6-1), a solidified film formation step of forming a solidified film of cyclohexanone oxime by solidifying the liquid film of the processing liquid (Step S6-2) and a sublimation step of removing the solidified film from the front surface Wf of the substrate W by sublimating the solidified film (Step S6-3).

In Step S6-1, the controller 4 causes the second guard 85 to face the peripheral end surface of the substrate W by controlling the second guard elevating/driving mechanism 88 and raising the second guard 85 to the upper position. Then, the controller 4 opens the valve 642. In that way, as shown in the right-upper stage of FIG. 7, the processing liquid (supersaturated cyclohexanone oxime solution) is discharged as the drying auxiliary liquid toward the central part of the front surface Wf of the substrate W having the IPA adhered thereto from the discharge port 53a of the nozzle 53 and supplied to the front surface Wf of the substrate W. The processing liquid on the front surface Wf of the substrate W spreads over the entire front surface Wf of the substrate W by receiving the centrifugal force caused by the rotation of the substrate W. In this way, the IPA adhering to the front surface Wf is replaced by the processing liquid in the entire front surface W of the substrate W and a liquid film LF of the processing liquid is formed on the front surface Wf as shown in the right-upper stage of FIG. 7. Further, the substrate processing liquid shaken off from the substrate W is collected by the second guard 85 and recovered by the second cup 82. Then, the recovered substrate processing liquid is fed to the purification apparatus 500 through the recovery piping 821. Furthermore, a purification process of the substrate processing liquid which is performed by the purification apparatus 500 will be described in detail later.

Though part of the substrate processing liquid spread entirely on the front surface Wf of the substrate W enters the inside of the pattern PT, the present invention is different from the invention disclosed in JP 2021-9988A in the following point. Specifically, the concentration of the cyclohexanone oxime particles which are uniformly dispersed in the substrate processing liquid entering the inside of the pattern PT is high. More specifically, the concentration reaches four to four hundred times as high as the concentration shown in JP 2021-9988A. Moreover, since the substrate processing liquid is in a state where the cyclohexanone oxime particles are uniformly dispersed with a concentration exceeding the solubility, i.e., in the metastable state, when the substrate processing liquid enters the inside of the pattern PT, to thereby reduce flow diffusion, recrystallization of the cyclohexanone oxime particles is started. Furthermore, in the present embodiment, the above-described recrystallization is further accelerated due to evaporation of a solvent component in the substrate processing liquid, i.e., IPA by the rotation of the substrate W and the next supply of nitrogen gas (Step S6-2).

Further, also after the metastable state is cancelled, the rotation of the substrate W and the supply of nitrogen gas are continued. In other words, in Step S6-2, the controller 4 opens the valve 652, and as shown in the right-middle stage of FIG. 7, the dehumidified nitrogen gas is discharged toward the front surface Wf of the substrate W rotating while being covered with the liquid film LF of the substrate processing liquid. As a result, a solidified film SF of the high concentration cyclohexanone oxime is formed inside the pattern PT. Herein, the timing of opening the valve 652, i.e., the timing of starting discharge of nitrogen gas may be before or after the start of recrystallization of the cyclohexanone oxime particles. Further, though the discharge of nitrogen gas is not indispensable for forming the solidified film of cyclohexanone oxime, it is desirable that the discharge of nitrogen gas should be also performed in order to improve the throughput.

Subsequently, the controller 4 performs the sublimation step (S6-3). The controller 4 causes the third guard 85 to face the peripheral end surface of the substrate W by controlling the second guard elevating/driving mechanism 88 and lowering the second guard 85 to the lower position. Note that although the controller 4 keeps the rotation speed of the substrate W from the formation step of the solidified film SF (Step S6-2), the rotation speed may be accelerated to a higher speed. Further, the controller 4 rotates the blocking plate 51 in the same direction and at the same speed as the rotation of the substrate W by controlling the blocking plate rotating/driving mechanism 55. According to the rotation of the substrate W, a contact speed of the solidified film SF with a surrounding atmosphere increases. In this way, the sublimation of the solidified film SF can be promoted and the solidified film SF can be sublimated in a short time. However, the rotation of the blocking plate 51 is not essential, but arbitrary in the sublimation step.

Further, in the sublimation step S6-3, the controller 4 keeps the open state of the valve 652 from the formation of the solidified film SF and the dehumidified nitrogen gas is discharged toward the central part of the front surface Wf of the substrate W in a rotating state from the discharge port 53a of the nozzle 53 as shown in the right-lower stage of FIG. 7. In this way, the sublimation step can be performed while a blocking space sandwiched between the front surface Wf of the substrate W and the substrate facing surface 51a of the blocking plate 51 is held in a low humidity state. In this sublimation step S6-3, heat of sublimation is deprived of as the solidified film SF is sublimated, and the solidified film SF is maintained at a temperature equal to or lower than the freezing point (melting point) of cyclohexanone oxime. Thus, the melting of the sublimable substance, i.e. cyclohexanone oxime, constituting the solidified film SF can be effectively prevented. Since no liquid phase is present between the pattern elements of the pattern PT on the front surface Wf of the substrate W in this way, the substrate W can be dried while a problem of the collapse of the pattern PT is mitigated.

Upon the elapse of a sublimation time determined in advance after the start of the sublimation drying step S6, the controller 4 stops the rotation of the spin chuck 3 by controlling the motor of the substrate rotating/driving mechanism 34 in Step S7. Further, the controller 4 stops the rotation of the blocking plate 51 by controlling the blocking plate rotating/driving mechanism 55 and raises the blocking plate 51 from the blocking position to the retracted position and positions the blocking plate 51 by controlling the blocking plate elevating/driving mechanism 56. Furthermore, the controller 4 retracts all the guards 86 to 88 downward from the peripheral end surface of the substrate W by controlling the third guard elevating/driving mechanism 89 and lowering the third guard 86.

Thereafter, after the controller 4 opens the shutter 23 (FIGS. 2 and 3) by controlling the shutter opening/closing mechanism 22, the substrate conveyor robot 111 enters the internal space of the chamber 2 and carries out the processed substrate W released from the chuck pins 31 to the outside of the chamber 2 (Step S8). Note that if the carry-out of the substrate W is completed and the substrate conveyor robot 111 is separated from the processing apparatus 1, the controller 4 closes the shutter 23 by controlling the shutter opening/closing mechanism 22.

Thus, though the substrate W is dried by using one of the sublimable substances for sublimation drying, i.e., cyclohexanone oxime, in the present embodiment, like in the invention disclosed in JP 2021-9988A, these inventions are significantly different in the cyclohexanone oxime (solid phase) existing inside the pattern PT. Specifically, in the present embodiment, a large amount of cyclohexanone oxime (solid phase) exists inside the pattern PT and it is possible to effectively suppress the solvent component (IPA) from remaining. In other words, it is possible to perform sublimation drying in a state where the patterns PT are firmly held by the cyclohexanone oxime (solid phase). For this reason, it is possible to suppress the occurrence of pattern collapse as compared with the invention disclosed in JP 2021-9988A.

Further, in the present embodiment, the substrate processing liquid shaken off from the substrate W is recovered by the second cup 82, and the recovered substrate processing liquid is purified by the purification apparatus 500 and reused. In other words, it is possible to suppress the amount of cyclohexanone oxime to be used, which is relatively expensive, and ensure reduction of the running cost.

Furthermore, as described next, the purification apparatus 500 increases the purity of cyclohexanone oxime by using the recrystallization of the cyclohexanone oxime particles in the metastable state. For this reason, it is possible to reduce the liquid-borne particles contained in the substrate processing liquid and further reduce the occurrence of pattern collapse.

### <Purification Apparatus>

When the substrate processing liquid containing the cyclohexanone oxime particles in the metastable state is left undone, the cyclohexanone oxime particles is recrystallized by the amount exceeding the solubility. When the transparent glass container GC storing therein the substrate processing liquid having the composition shown in the column (d) of FIG. 1 is left at rest at room temperature, for example, the cyclohexanone oxime is deposited in the transparent glass container GC. In analyzing the deposit by Fourier transform infrared spectroscopy and gas chromatography analysis (using a hydrogen flame ionization detector (HFID)), it is verified that the deposit is cyclohexanone oxime (solid phase) having a purity of 99.99%. In other words, even though the substrate processing liquid contains liquid-borne particles, high purity cyclohexanone oxime (solid phase) can be obtained by using the recrystallization. Then, by adding an auxiliary agent (NH₄OH) to a solution in which the deposited cyclohexanone oxime (solid phase) is dissolved in a solvent (IPA), it is possible to purify the solution to thereby obtain a high purity substrate processing liquid (a supersaturated solution of cyclohexanone oxime) containing no liquid-borne particle.

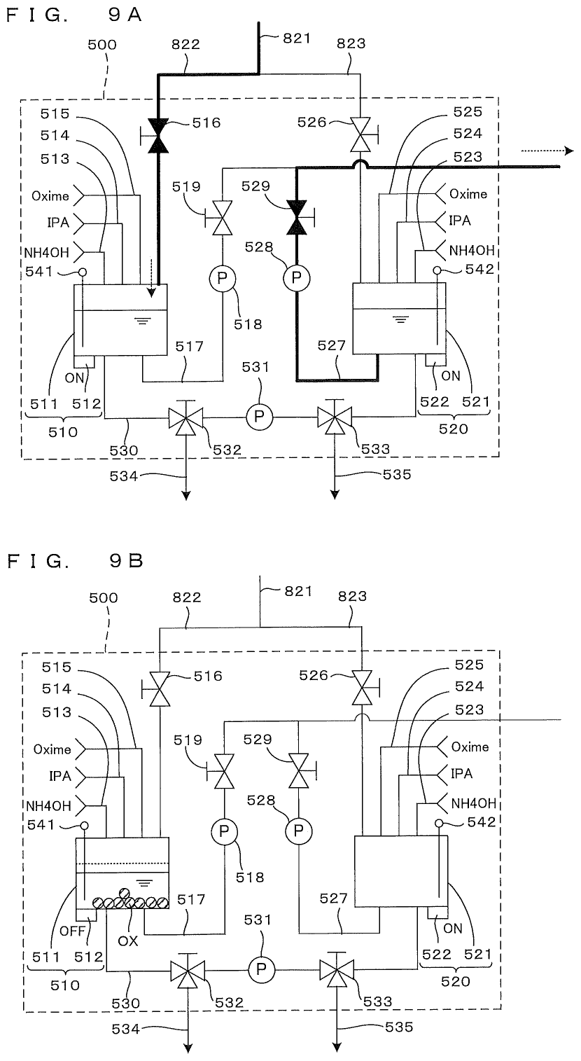

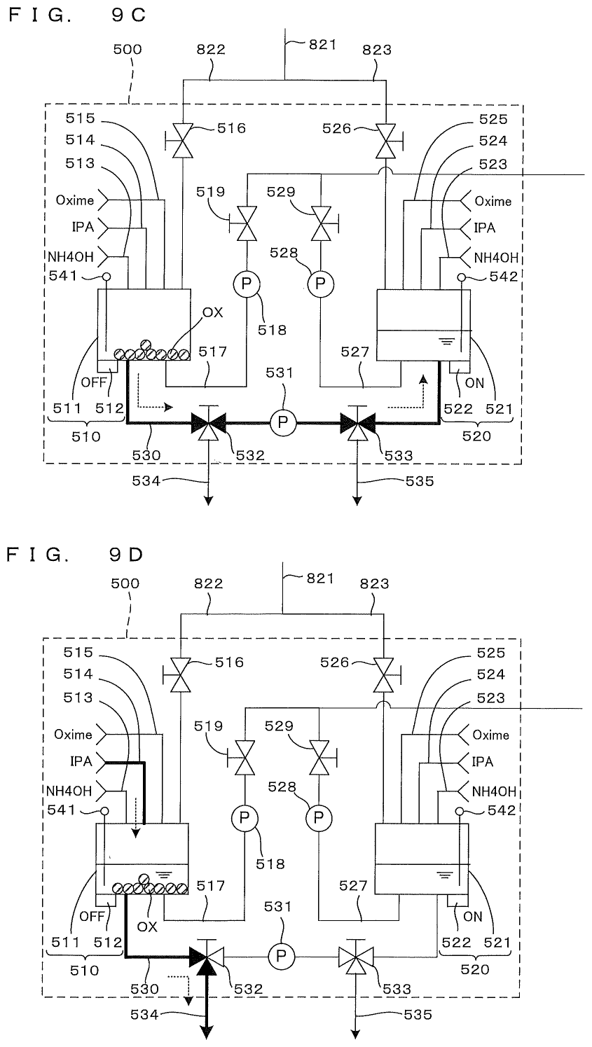

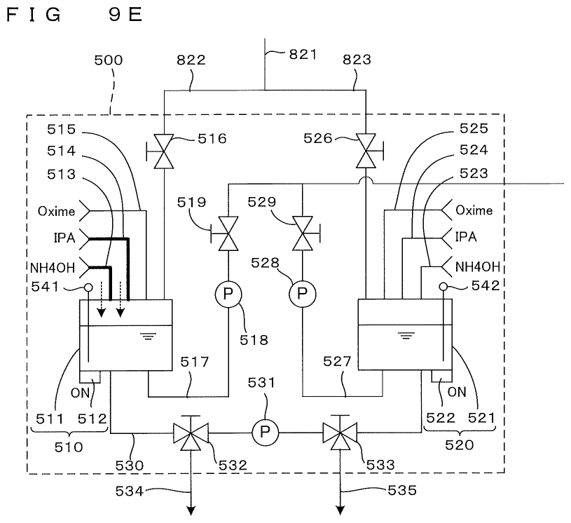

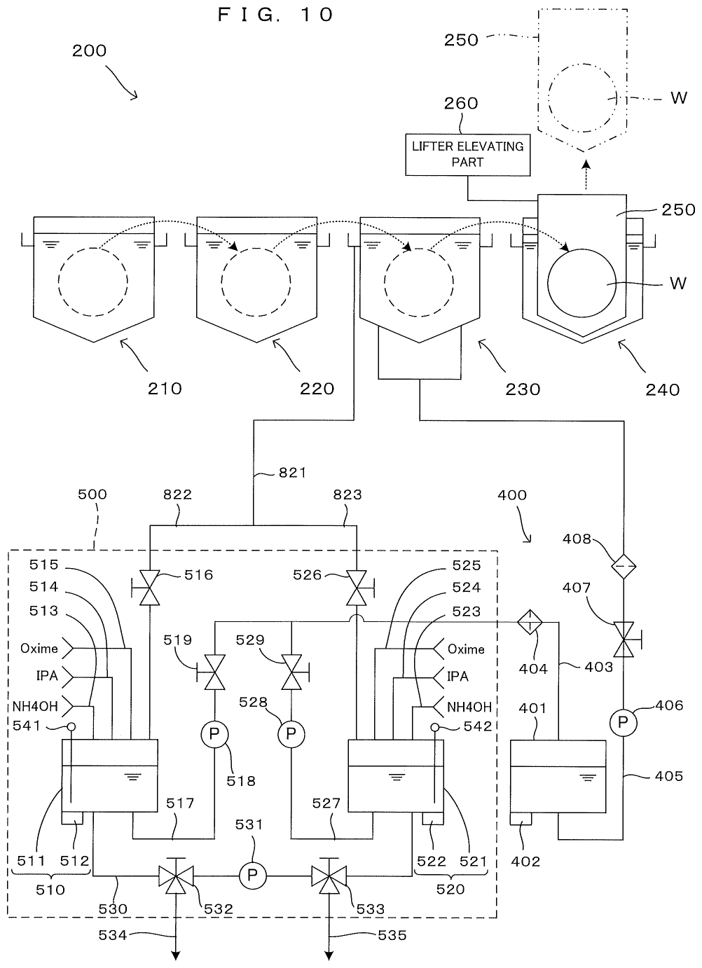

Then, in the present embodiment, the purification apparatus 500 shown in FIG. 6 is incorporated in the substrate processing apparatus 1. Hereinafter, with reference to FIG. 6, a configuration of the purification apparatus 500 will be described and then with reference to FIGS. 8 and 9A to 9E, an operation of the purification apparatus 500 will be described.

As shown in FIG. 6, the purification apparatus 500 has two ultrasonic baths 510 and 520. The ultrasonic bath 510 has a bath 511 capable of storing therein the substrate processing liquid and an ultrasonic wave applying part 512 attached to the bath 511. An operation of the ultrasonic wave applying part 512 is controlled in response to a command from the controller 4. When the ultrasonic wave applying part 512 starts operating in response to an operation command from the controller 4 in a state where the substrate processing liquid containing the cyclohexanone oxime particles in the metastable state is stored in the ultrasonic bath 510, the ultrasonic vibration is applied to the substrate processing liquid stored in the bath 511 and the metastable state is kept. On the other hand, when the ultrasonic wave applying part 512 stops in response to an operation stop command from the controller 4, the recrystallization of the cyclohexanone oxime particles proceeds in the ultrasonic bath 510, and high purity cyclohexanone oxime (solid phase) is deposited in the bath 511. Further, like the ultrasonic bath 510, the ultrasonic bath 520 also has a bath 521 capable of storing therein the substrate processing liquid and an ultrasonic wave applying part 522 attached to the bath 521 and performs the same functions.

The ultrasonic baths 510 and 520 are connected to each other with a coupling piping 530. One end of the coupling piping 530 is connected to a bottom of the ultrasonic bath 510, and the other end thereof is connected to a bottom of the ultrasonic bath 520. Further, a pump 531 is disposed in a central part of the coupling piping 530. Furthermore, a three-way valve 532 is interposed between one end of the coupling piping 530 and an interposed position of the pump 531 and a three-way valve 533 is interposed between the other end of the coupling piping 530 and the above-described interposed position. When the pump 531 operates in response to a command from the controller 4 and the three-way valves 532 and 533 are switched to feeding positions (see FIG. 9C) in response to a command from the controller 4, the substrate processing liquid is fed between the ultrasonic baths 510 and 520. Further, the three-way valves 532 and 533 have a first port and a second port for controlling the feed of the substrate processing liquid and further have a third port for discharging a liquid from the ultrasonic bath 510. For this reason, by opening the first port and the third port of the three-way valve 532 while closing all the ports of the three-way valve 533 in response to the command from the controller 4, the liquid can be discharged from the ultrasonic bath 510 through a piping 534 (see FIG. 9D). Further, by opening the first port and the third port of the three-way valve 533 while closing all the ports of the three-way valve 532 in response to the command from the controller 4, the liquid can be discharged from the ultrasonic bath 520 through a piping 535.

Furthermore, to the ultrasonic bath 510, connected are pipings 513 to 515. The piping 515 is connected to a supply source of the cyclohexanone oxime. The ultrasonic bath 510 is replenished with the cyclohexanone oxime from the supply source in response to a replenishment command from the controller 4. Further, the cyclohexanone oxime (solid phase) or a relatively high concentration cyclohexanone oxime solution in which the cyclohexanone oxime is dissolved in a solvent which is the same as the solvent component in the above-described substrate processing liquid may be supplied from the supply source.

The piping 514 is connected to a supply source of the solvent (IPA in the present embodiment) of the substrate processing liquid. The ultrasonic bath 510 is supplied with the IPA from the supply source in response to a supply command from the controller 4.

The piping 513 is connected to a supply source of the auxiliary agent (aqueous ammonia in the present embodiment) of the substrate processing liquid. The ultrasonic bath 510 is supplied with the aqueous ammonia from the supply source in response to a supply command from the controller 4.

Further, a branch piping 822 of the recovery piping 821 extending from the second cup 82 is extended to the ultrasonic bath 510 and guides the used substrate processing liquid recovered by the second cup 82 to the ultrasonic bath 510. In this branch piping 822, a valve 516 is disposed and controlled to open and close in response to an open/close command from the controller 4. Specifically, when the valve 516 is opened, the recovered substrate processing liquid is fed to the ultrasonic bath 510 (recovery process). Conversely, when the valve 516 is closed, feeding of the recovered substrate processing liquid to the ultrasonic bath 510 is stopped.

Furthermore, the ultrasonic bath 510 is provided with a concentration meter 541 for measuring the concentration of the cyclohexanone oxime in the ultrasonic bath 510.

Thus, the cyclohexanone oxime, the IPA, the NH₄OH, and the used substrate processing liquid can be supplied to the ultrasonic bath 510 independently of one another. Therefore, when it is sensed, from a measurement result by the concentration meter 541, that the concentration of cyclohexanone oxime in the substrate processing liquid stored in the ultrasonic bath 510 is low, the controller 4 increases the concentration to be higher than the saturation concentration by supplying the cyclohexanone oxime. Further, by adding the IPA to the substrate processing liquid stored in the ultrasonic bath 510, the concentration of cyclohexanone oxime can be adjusted. Furthermore, by replenishing the substrate processing liquid containing the cyclohexanone oxime whose concentration exceeds the saturation concentration, with NH₄OH, the cyclohexanone oxime particles can be adjusted to be in the metastable state. Furthermore, as described later, by supplying the IPA in a state where only the cyclohexanone oxime (solid phase) deposited in the ultrasonic bath 510 is left in the ultrasonic bath 510, it is also possible to thinly strip a surface layer of the deposit (cyclohexanone oxime (solid phase)) and remove the impurities adhered to the deposit. Only high purity cyclohexanone oxime (solid phase) is thereby left in the ultrasonic bath 510, and by supplying the IPA and the NH₄OH with a moderate amount, it is possible to obtain the substrate processing liquid containing high purity cyclohexanone oxime particles in the metastable state (purification process).

In order to feed the substrate processing liquid which is purified thus to the storage tank 401, provided is a piping 517 for connecting the bottom of the ultrasonic bath 510 and the piping 403. In the piping 517, a pump 518 and a valve 519 are disposed. When the pump 518 starts operating in response to an operation command from the controller 4 in a state where the valve 519 is opened in response to an open command from the controller 4, the above-described purified substrate processing liquid is fed to the storage tank 401 through the piping 517. A replenishment process of the substrate processing liquid is thereby performed. Thus, in the ultrasonic bath 510, it is possible to alternately perform the recovery/purification process and the replenishment process.

Like in the case of the ultrasonic bath 510, to the other ultrasonic bath 520, connected are pipings 523 to 525. Then, it is possible to perform replenishment of the cyclohexanone oxime through the piping 525 on the basis of a measurement result of a concentration meter 542, supply of the IPA (solvent) through the piping 524, and replenishment of the aqueous ammonia (auxiliary agent) through the piping 523 independently of one another. Further, a branch piping 823 of the recovery piping 821 extending from the second cup 82 is connected to the ultrasonic bath 520, and when a valve 526 disposed in the branch piping 823 is opened, the recovered substrate processing liquid is fed to the ultrasonic bath 520. Conversely, when the valve 526 is closed, feeding of the recovered substrate processing liquid to the ultrasonic bath 520 is stopped. Also in the ultrasonic bath 520 like in the ultrasonic bath 510, it is possible to alternately perform the recovery/purification process and the replenishment process.

FIG. 8 is a flowchart showing an operation of the purification apparatus shown in FIG. 6. FIGS. 9A to 9E are views each schematically showing an exemplary operation of the purification apparatus shown in FIG. 6. In these figures, reference signs “ON” and “OFF” represent “operating” and “stop operating” of the ultrasonic wave applying parts 512 and 522, respectively, and in the marks representing the valve and the three-way valve, black triangle represents an open state of the port and the valve and white triangle represents a close state of the port and the valve. Further, a thick line represents a flow of the liquid. Constituent elements of the purification apparatus 500 perform the following operations in accordance with a purification program stored in the controller 4 in advance, concurrently with the substrate processing shown in FIG. 6, which is performed by the substrate processing apparatus 1. Concurrently with the recovery/purification process performed in one of the ultrasonic baths 510 and 520, the replenishment process is thereby performed in the other one of the ultrasonic baths 510 and 520. Further, though the controller 4 for controlling the whole of the substrate processing apparatus 1 controls the purification apparatus 500 in the present embodiment, a dedicated controller for controlling the purification apparatus 500 may be provided to control the constituent elements of the purification apparatus 500.

The controller 4 sets respective functions of the ultrasonic baths 510 and 520 so that an ultrasonic bath for performing the recovery/purification process and another ultrasonic bath for performing the replenishment process can be alternately switched over in Step S11. Herein, description will be made assuming that the controller 4 sets the functions so that the ultrasonic baths 510 and 520 can perform the recovery/purification process and the replenishment process, respectively, in Step S11. At this point in time, the valves 516 and 526 are closed and the supply of the substrate processing liquid recovered by the second cup 82 to the purification apparatus 500 is stopped. Further, all the ports of the three-way valves 532 and 533 are closed, and passage of an unpurified substrate processing liquid (a substrate processing liquid before purification) (hereinafter, referred to as an “unpurified processing liquid”) between the ultrasonic baths 510 and 520 is thereby regulated. Furthermore, both the ultrasonic baths 510 and 520 operate, and the unpurified processing liquid is stored in the ultrasonic bath 510 while the purified substrate processing liquid is stored in the ultrasonic bath 520.

In the ultrasonic bath 520 for performing the replenishment process, as shown in FIG. 9A, when a valve 529 is opened, a pump 528 starts operating. The purified substrate processing liquid is thereby fed toward the storage tank 401 (FIG. 6) of the processing liquid supply part 400 through a piping 527 (Step S12). Further, as the substrate processing liquid is fed, the amount of substrate processing liquid stored in the ultrasonic bath 520 gradually decreases and finally becomes vacant (“YES” in Step S13). Then, the pump 528 is stopped and the valve 529 is closed (Step S14). The replenishment process is thereby completed.

Concurrently with the replenishment process, in the ultrasonic bath 510, the recovery/purification process is performed (Steps S15 to S19). In Step S15, as shown in FIG. 9A, the valve 516 is opened, and the substrate processing liquid recovered by the second cup 82 is recovered through the pipings 821 and 822 to the ultrasonic bath 510 serving as an ultrasonic bath for purification and mixed with the unpurified processing liquid which is already stored. When this is finished, the valve 516 is closed.

When it is found, from the measurement result by the concentration meter 541, that the concentration of the cyclohexanone oxime particles contained in the unpurified processing liquid is not higher than the saturation concentration, i.e., when the unpurified processing liquid is not supersaturated (“NO” in Step S16), the cyclohexanone oxime, the IPA, or the NH₄OH is supplied to the ultrasonic bath 510, and after the concentration of the cyclohexanone oxime particles contained in the unpurified processing liquid is adjusted (Step S17), the process goes back to Step S16.

On the other hand, when it is verified that the concentration of the cyclohexanone oxime particles is higher than the saturation concentration and the unpurified processing liquid which is supersaturated exists in the ultrasonic bath 510 (“YES” in Step S16), as shown in FIG. 9B, the ultrasonic wave applying part 512 is stopped and application of the ultrasonic vibration to the unpurified processing liquid is stopped (Step S18). The recrystallization of the cyclohexanone oxime particles in the metastable state is thereby started, and the cyclohexanone oxime (solid phase) OX is deposited in the ultrasonic bath 510. When it is verified, on the basis of the measurement result by the concentration meter 541, that the recrystallization is completed and the replenishment process is also completed, as shown in FIG. 9C, the first and second ports of the three-way valves 532 and 533 are opened and the pump 531 starts operating and the unpurified processing liquid stored in the ultrasonic bath 510 is transferred to the vacant ultrasonic bath 520 through the piping 530. In other words, the unpurified processing liquid is fed from the ultrasonic bath 510 for purification to the vacant ultrasonic bath 520 (Step S19), and the ultrasonic bath 520 receives the unpurified processing liquid from the ultrasonic bath 510 for purification (Step S20). While only the deposit (cyclohexanone oxime (solid phase)) is thereby left in the ultrasonic bath 510, the unpurified processing liquid containing the cyclohexanone oxime particles whose concentration is not higher than the saturation concentration is stored in the ultrasonic bath 520, being in a state similar to that of the ultrasonic bath 510 before the recovery/purification process is started.

When the transfer of the unpurified processing liquid is completed, the pump 531 is stopped. Further, the first port and the second port of the three-way valves 532 and 533 are closed. Then, as shown in FIG. 9D, only the IPA is supplied to the ultrasonic bath 510. The surface layer of the deposit is thereby thinly stripped and the impurities adhered to the deposit is removed. In other words, the cyclohexanone oxime (solid phase) OX is cleaned. After this cleaning, the first port and the third port of the three-way valve 532 are opened, and the IPA after cleaning is discharged together with the impurities from the ultrasonic bath 510 along the waste liquid path consisting of the piping 530, the three-way valve 532, and the piping 534. By repeating the cleaning of the deposit, high purity cyclohexanone oxime (solid phase) OX is obtained (Step S21). Subsequently, as shown in FIG. 9E, the IPA and the NH₄OH are supplied to the ultrasonic bath 510 and the operation of the ultrasonic wave applying part 512 is resumed. The supersaturated substrate processing liquid is thereby purified and stored in the ultrasonic bath 510 as the substrate processing liquid suitable for sublimation drying, like in the ultrasonic bath 520 before the above-described replenishment process is performed (Step S22).

Thus, when the replenishment process and the recovery/purification process are completed, the process goes back to Step S11 and the replenishment process and the recovery/purification process are repeated. Specifically, in each of the ultrasonic baths 510 and 520, the replenishment process, the recovery/purification process, and the replenishment process are performed.

As described above, in the purification apparatus 500, the substrate processing liquid is purified by using the cyclohexanone oxime (solid phase) OX obtained by recrystallization of the cyclohexanone oxime particles in the metastable state. Therefore, the substrate processing liquid not containing any impurities, liquid-borne particles, or the like can be obtained. Then, by performing sublimation drying using this substrate processing liquid, it is possible to further suppress collapse of the pattern PT.

### <Batch Type Substrate Processing System>

The present invention is applied not only to the single wafer type substrate processing apparatus but can be also applied to a substrate processing apparatus equipped in a so-called batch type substrate processing system.

FIG. 10 is a view showing a configuration of a substrate processing system equipped with a second embodiment of the substrate processing apparatus in accordance with the present invention. A substrate processing system 200 is a batch type substrate processing system for collectively processing a plurality of substrates W. The substrate processing system 200 includes a chemical liquid storage bath 210 for storing therein a chemical liquid, a rinse liquid storage bath 220 for storing therein a rinse liquid (e.g., water), a sublimation agent storage bath 230 for storing therein a substrate processing liquid for sublimation drying which is used in the first embodiment, and a supply liquid storage bath 240 for storing therein a supply liquid (e.g., a water-containing liquid). Further, to the sublimation agent storage bath 230, connected is the piping 405 extending from the above-described processing liquid supply part 400. Furthermore, the substrate processing liquid recovered by an overflow bath provided in the sublimation agent storage bath 230 is recovered to the purification apparatus 500 through the piping 821. The purification apparatus 500 performs the recovery/purification process. Then, the purified substrate processing liquid is returned to the sublimation agent storage bath 230 through the processing liquid supply part 400. Further, though not shown in FIG. 10, an ultrasonic generator disclosed in, for example, JP 2021-034442A is provided below the sublimation agent storage bath 230, to thereby allow switching between application of the ultrasonic wave to the substrate processing liquid in the sublimation agent storage bath 230 and stop of the application.

The substrate processing system 200 further includes a lifter 250 for immersing the substrate W in a supply liquid stored in the supply liquid storage bath 240 and a lifter elevating part 260 for moving the lifter 250 up and down. The lifter 250 supports each of the plurality of substrates W in a vertical posture. The lifter elevating part 260 moves the lifter 250 up and down between a processing position (the position indicated by a solid line in FIG. 10) where the substrate W held by the lifter 250 is positioned inside the supply liquid storage bath 240 and an escape position (the position indicated by a two-dot chain line in FIG. 10) where the substrate W held by the lifter 250 is escaped upward from the inside of the supply liquid storage bath 240.

In a series of processings performed in the substrate processing system 200, the plurality of substrates W loaded in a processing unit of the substrate processing system 200 are immersed in the chemical liquid stored in the chemical liquid storage bath 210. A chemical liquid processing (a cleaning process and an etching process) is thereby performed on each substrate W (a chemical liquid process). When a predetermined period elapses from the start of immersing the substrates W in the chemical liquid, the plurality of substrates W are pulled up from the chemical liquid storage bath 210 and transferred to the rinse liquid storage bath 220. Next, the plurality of substrates W are immersed in the rinse liquid stored in the rinse liquid storage bath 220. The rinsing processing is thereby performed on the substrates W (a rinsing process). When a predetermined period elapses from the start of immersing the substrates W in the rinse liquid, the plurality of substrates W are pulled up from the rinse liquid storage bath 220 and transferred to the sublimation agent storage bath 230. Next, the plurality of substrates W are immersed in the substrate processing liquid stored in the sublimation agent storage bath 230. When a predetermined period elapses from the start of immersing the substrates W in the substrate processing liquid, the plurality of substrates W are pulled up from the sublimation agent storage bath 230. In pulling up the substrates W, the cyclohexanone oxime particles in the substrate processing liquid are deposited, and formation of a solidified film on the front surface of each substrate W is started. Then, the substrates W each having the solidified film are transferred to the supply liquid storage bath 240.

The solidified film of the substrate processing liquid is formed on the entire front surface of each substrate W which is transferred to the supply liquid storage bath 240. Then, by controlling the lifter elevating part 260 to move the lifter 250 from the escape position to the processing position, the plurality of substrates W held by the lifter 250 are immersed in the supply liquid.

When a predetermined period elapses from the start of immersing the substrates W in the supply liquid, the lifter elevating part 260 is controlled to move the lifter 250 from the processing position to the escape position. The plurality of substrates W immersed in the supply liquid are thereby pulled up from the supply liquid.

In pulling up the substrates W from the supply liquid, pulling dry (a supply liquid removal process) is performed. Pulling dry is performed by spraying a gas (e.g., an inert gas such as nitrogen gas or the like) to the front surface of the substrate W pulled up from the supply liquid storage bath 240 and pulling up the substrates W at a relatively low speed (e.g., several mm/second). The supply liquid is thereby removed from the entire front surface of the substrate W.

After that, the solidified film, i.e., the cyclohexanone oxime (solid phase) is sublimated into gas. Since the solidified film can be thereby removed from the front surface of the substrate W without passing through a liquid state, it is possible to dry the front surface of the substrate W while effectively suppressing or preventing the pattern collapse.

In the above-described embodiment, purification of the substrate processing liquid by the purification apparatus 500 corresponds to one example of an “operation (a)” of the present invention, Steps S15 to S17 in FIG. 8 correspond to one example of an “operation (a-1)” of the present invention, Step S18 corresponds to one example of an “operation (a-2)” of the present invention, Steps S21 and S22 correspond to one example of an “operation (a-3)” of the present invention, and Step S12 corresponds to one example of an “operation (a-4)” of the present invention. Further, the storage tank 401 corresponds to one example of a “storage part” of the present invention.

Furthermore, the present invention is not limited to the above-described embodiments and numerous modifications and variations can be added to those described above without departing from the scope of the invention. Though the recovered substrate processing liquids are mixed and used by the purification apparatus 500 in the above-described embodiments, for example, the above-described mixture is not indispensable but arbitrary. In terms of ensuring reduction in the running cost, or the like, however, the above-described mixture is useful.

Further, though the cleaning process is performed on the deposited cyclohexanone oxime OX in the above-described embodiments, this process may be omitted.

Furthermore, in the above-described embodiments, the unpurified processing liquid reciprocates between the ultrasonic baths 510 and 520, and as the number of reciprocations increases, the impurities, the liquid-borne particles, or the like increase in the unpurified processing liquid. Then, there may be a configuration where when the number of reciprocations reaches a certain value, the unpurified processing liquid is discharged through the pipings 534 and 535.

Further, though the substrate processing liquid purified by the purification apparatus 500 is used in the above-described embodiments, it is not indispensable to perform the purification process. For example, by adding an auxiliary agent when the sublimable substance (solid phase) is dissolved in the solvent, a supersaturated solution of the sublimable substance in which the particles of the sublimable substance, the amount of which exceeds the solubility, are uniformly dispersed in the solution, may be used as the substrate processing liquid.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

The present invention can be applied to general substrate processing liquid used for removing a liquid adhered to a substrate by using a sublimation phenomenon of a sublimable substance and general substrate processing technique for removing the above-described liquid from the substrate by using the substrate processing liquid.

What is claimed is:

1. A substrate processing liquid used for removing a liquid on a substrate having a pattern formation surface, comprising:
a sublimable substance;
a solvent that dissolves the sublimable substance; and
an auxiliary agent that is added to a solution in which the sublimation substance is dissolved in the solvent to disperse particles of the sublimation substance exceeding the solubility in the solution.

2. The substrate processing liquid according to claim 1, wherein
the auxiliary agent is a crystallization inhibitor for inhibiting crystallization of the sublimable substance in the solution.

3. The substrate processing liquid according to claim 1, wherein
the sublimable substance is cyclohexanone oxime, and
the auxiliary agent performs pH adjustment of the solution so that the zeta potential of the sublimable substance in the solution becomes negative.

4. The substrate processing liquid according to claim 3, wherein
the auxiliary agent is aqueous ammonia.

5. A substrate processing method, comprising:
(a) preparing the substrate processing liquid according to claim 1;
(b) supplying the substrate processing liquid prepared in the operation (a) onto a front surface of a substrate on which a pattern is formed, to thereby form a liquid film of the substrate processing liquid on the front surface of the substrate;
(c) solidifying the liquid film of the substrate processing liquid, to thereby form a solidified film of the sublimable substance; and
(d) sublimating the solidified film, to thereby remove the solidified film from the front surface of the substrate.

6. The substrate processing method according to claim 5, wherein
the operation (a) includes storing the substrate processing liquid in a storage bath to which ultrasonic vibration is applied.

7. The substrate processing method according to claim 6, wherein
the operation (a) has
(a-1) preparing a supersaturated solution of the sublimable substance;
(a-2) depositing the sublimable substance from the supersaturated solution;
(a-3) purifying the substrate processing liquid by adding the auxiliary agent to a solution in which the deposited sublimable substance is dissolved in the solvent; and
(a-4) replenishing the storage bath with the substrate processing liquid purified in the operation (a-3).

8. The substrate processing method according to claim 7, wherein
the operation (a-3) includes cleaning the deposited sublimable substance before dissolving the deposited sublimable substance in the solvent.

9. The substrate processing method according to claim 7, wherein
the operation (a-1) is performed in an ultrasonic bath to which ultrasonic vibration is applied;
the operation (a-2) is performed by stopping application of an ultrasonic wave to the ultrasonic bath storing therein the supersaturated solution; and
the operation (a-3) is performed by resuming application of ultrasonic vibration to the ultrasonic bath.

10. The substrate processing method according to claim 6, wherein
the operation (b) includes discharging the substrate processing liquid to the front surface of the substrate from a nozzle, to thereby supply the substrate processing liquid onto the front surface of the substrate, while applying ultrasonic vibration to the substrate processing liquid inside the nozzle.

11. The substrate processing method according to claim 10, wherein
the operation (b) includes feeding the substrate processing liquid to the nozzle from the storage bath while applying ultrasonic vibration to the substrate processing liquid.

12. A substrate processing apparatus, comprising:
a storage part configured to store therein the substrate processing liquid according to claim 1, and
a processing liquid supply part configured to supply the substrate processing liquid stored in the storage part onto a front surface of a substrate on which a pattern is formed.
